(19) United States
(12) Patent Application Publication
(10) Pub. No.: US 2008/0232443 A1
(43) Pub. Date: Sep. 25, 2008

(54) SIGNAL GENERATING APPARATUS

(76) Inventors: Tai-Yuan Yu, Taoyuan County (TW); Ping-Ying Wang, Hsinchu City (TW); Ling-Wei Ke, Hsin-Chu Hsien (TW); Hsin-Hung Chen, Miaoli County (TW)

Correspondence Address: NORTH AMERICA INTELLECTUAL PROPERTY CORPORATION, P.O. BOX 506, MERRIFIELD, VA, 22116, US

(21) Appl. No.: 12/107,768

(22) Filed: Apr. 23, 2008

Related U.S. Application Data
(63) Continuation-in-part of application No. 11/690,145, filed on Mar. 23, 2007, now Pat. No. 7,382,201.

(51) Int. Cl. H03K 11/00

(52) U.S. Cl. 375/215

(57) ABSTRACT

A signal generating apparatus for generating a synthesized signal according to an input signal is provided. The signal generating apparatus includes a phase-locked loop device and a control unit. The phase-locked loop device has a phase/frequency detector for generating a detected signal according to a reference oscillating signal and a feedback signal, a control signal generator for generating a control signal according to the detected signal, a voltage controlled oscillator for generating the synthesized signal according to the control signal, and a divider for dividing the synthesized signal according to a dividing factor to generate the feedback signal. The control unit is for controlling the control signal generator to adjust the control signal in a calibration mode to thereby adjust a frequency of the synthesized signal. The phase/frequency detector does not output the detected signal to the control signal generator in the calibration mode.

### CROSS REFERENCE TO RELATED APPLICATIONS

This continuation-in-part application claims the benefit of the co-pending U.S. patent application Ser. No. 11/690,145, filed on Mar. 23, 2007 and included herein by reference.

### BACKGROUND

The present invention relates to a signal generating apparatus, and more particularly to a phase-locked loop based transmitter with an open loop modulation compensation scheme, wherein the modulation compensation scheme calibrates a compensation filter according to an output frequency of a controllable oscillator of the signal generating apparatus.

Please refer to FIG. 1. FIG. 1 is a related art Sigma-delta fractional N phase locked loop (PLL) transmitter 10. The Sigma-delta fractional N PLL transmitter 10 comprises a phase locked loop circuit 11, a Sigma-delta modulator 12, a channel selector 13, a Gaussian filter 14, and a compensation filter 15. The phase locked loop circuit 11 comprises a phase/frequency detector 11a, a charge pump circuit 11b, a loop filter 11c, a voltage-controlled oscillator 11d, and a divider 11e. The baseband data Sb is inputted to the Gaussian filter 14 to extract the required band of the Sigma-delta fractional N PLL transmitter 10. For example, if the transmitted signal of the Sigma-delta fractional N PLL transmitter 10 is the GMSK signal SGMSK, then the Gaussian filter 14 is the GMSK filter. Furthermore, as the frequency response of the phase locked loop circuit 11 acts like a low pass filter, the compensation filter 15 is utilized to compensate the baseband data Sb before being modulated by the Sigma-delta modulator 12. Furthermore, the phase locked loop circuit 11 utilizes a reference frequency Sr to synthesize the required frequency to transmit the baseband data Sb. In a multi-band system, the phase locked loop circuit 11 needs to generate different frequency bands, and the channel selector 13 is utilized to select the required frequency band. Accordingly, by adjusting the dividing number of the divider 11e, the phase locked loop circuit 11 can generate different frequency bands accordingly.

However, it is well-known that the loop bandwidth of the phase locked loop circuit 11 is sensitive to the transfer function of the phase locked loop circuit 11. To deal with this problem, some conventional techniques have been disclosed, such as U.S. Pat. Nos. 7,103,337, 7,068,112, 6,724,265, and U.S. Pat. No. 6,806,780.

### SUMMARY

One of the objectives of the present invention is to provide a phase-locked loop based transmitter with an open loop modulation compensation scheme, wherein the modulation compensation scheme calibrates a compensation filter according to an output frequency of a controllable oscillator of the signal generating apparatus.

According to an embodiment of the present invention, a signal generating apparatus for generating a synthesized signal according to an input signal is provided. The signal generating apparatus includes a phase-locked loop device and a control unit. The phase-locked loop device has a phase/frequency detector for generating a detected signal according to a reference oscillating signal and a feedback signal, a control signal generator coupled to the phase/frequency detector for generating a control signal according to the detected signal, a voltage controlled oscillator coupled to the control signal generator for generating the synthesized signal according to the control signal, and a divider coupled to the voltage controlled oscillator for dividing the synthesized signal according to a dividing factor for generating the feedback signal. The control unit is coupled to the control signal generator, and is for controlling the control signal generator to adjust the control signal in a calibration mode to thereby adjust a frequency of the synthesized signal. The phase/frequency detector does not output the detected signal to the control signal generator in the calibration mode.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a related art Sigma-delta fractional N phase locked loop (PLL) transmitter.

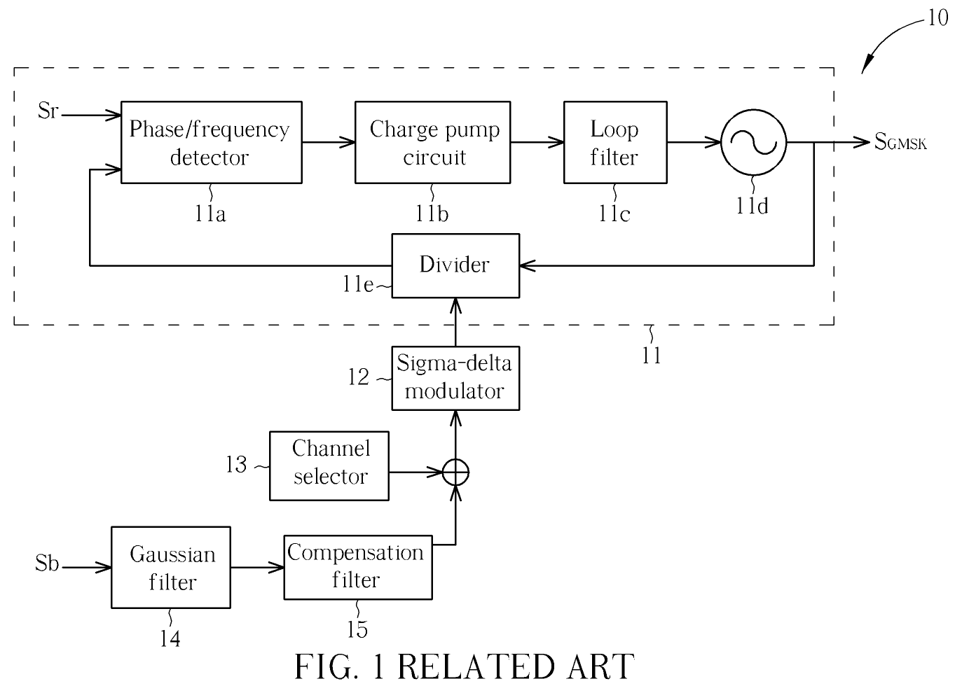

FIG. 2 is a diagram illustrating a first exemplary embodiment of a signal generating apparatus according to the present invention.

FIG. 3 is a diagram illustrating the detecting device and the control signal generator according to a first embodiment of the present invention.

FIG. 4 is a diagram illustrating a control signal generator according to a second embodiment of the present invention.

FIG. 5 is a flowchart illustrating a signal generating method employed by the signal generating apparatus as shown in FIG. 2.

FIG. 6 is a diagram illustrating a second exemplary embodiment of a signal generating apparatus according to the present invention.

FIG. 7 is a diagram illustrating a third exemplary embodiment of a signal generating apparatus according to the present invention.

FIG. 8 is a diagram illustrating a fourth exemplary embodiment of a signal generating apparatus according to the present invention.

### DETAILED DESCRIPTION

Certain terms are used throughout the following description and claims to refer to particular system components. As one skilled in the art will appreciate, manufacturers may refer to a component by different names. This document does not intend to distinguish between components that differ in name but not function. In the following discussion and in the claims, the terms “including” and “comprising” are used in an open-ended fashion, and thus should be interpreted to mean “including, but not limited to . . . “The terms “couple” and “couples” are intended to mean either an indirect or a direct electrical connection. Thus, if a first device couples to a second device, that connection may be through a direct electrical connection, or through an indirect electrical connection via other devices and connections.

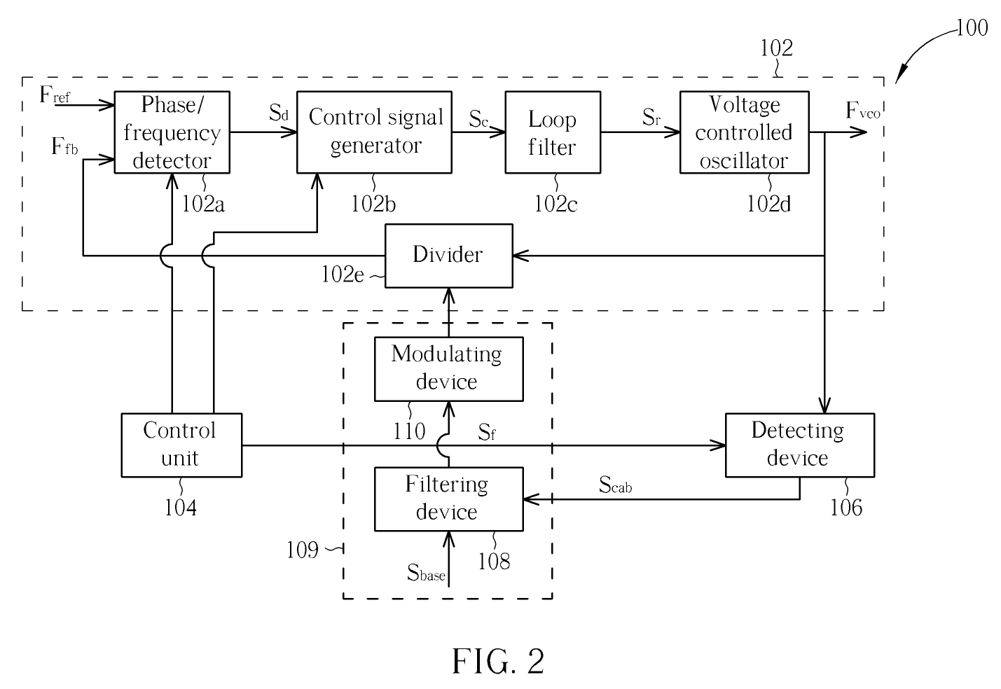

Please refer to FIG. 2. FIG. 2 is a diagram illustrating a first exemplary embodiment of a signal generating apparatus 100 according to the present invention. The signal generating apparatus 100 generates a synthesized signal F_{vco} according to an input signal S_{base}, and the signal generating apparatus 100 comprises a phase-locked loop device 102, a control unit 104, a detecting device 106, and a correction device 109 including a filtering device 108 and a modulating device 110. Please note that those skilled in this art will readily understand that the signal generating apparatus 100 can be implemented as a fractional N PLL (Phase-locked loop) synthesizer with an adaptive compensation filter, i.e., the filtering device 108. The phase-locked loop device 102 comprises a phase/frequency detector 102a, a control signal generator 102b, a loop filter 102c, a voltage controlled oscillator 102d, and a divider 102e. The phase/frequency detector 102a is coupled to a reference oscillating signal F_{ref} for generating a detected signal S_{d} according to the reference oscillating signal F_{ref} and a feedback signal F_{fb}. The control signal generator 102b is coupled to the phase/frequency detector 102a for generating a control signal S_{c} according to the detected signal S_{d}. The loop filter 102c is coupled to the control signal generator 102b for filtering the control signal S_{c} to generate a reference signal Sᵣ. The voltage controlled oscillator 102d is coupled to the loop filter 102c for generating the synthesized signal F_{vco} according to the control signal S_{c}. The divider 102e coupled to the voltage controlled oscillator 102d, the modulating device 110, and the phase/frequency detector 102a for dividing the synthesized signal F_{vco} according to a dividing factor N and outputting the feedback signal F_{fb} to phase/frequency detector 102a. The control unit 104 is coupled to the phase/frequency detector 102a, the control signal generator 102b, and the detecting device 106 for controlling the control signal generator 102b to adjust the control signal S_{c} in a calibration mode to thereby adjust a frequency of the synthesized signal F_{vco}, wherein the phase/frequency detector 102a is disabled by the control unit 104 in the calibration mode. In other words, the phase/frequency detector 102a does not output the detected signal S_{d} to the control signal generator 102b in the calibration mode. The detecting device 106 is coupled to the voltage controlled oscillator 102d for detecting the synthesized signal F_{vco} to generate a calibrating signal S_{cab} in the calibration mode. The filtering device 108 is coupled to the detecting device 106 and calibrated by the calibrating signal S_{cab}. After being calibrated, the filtering device 108 will filter the input data S_{base} to generate a filtered signal S_{f}. The modulating device 110 is coupled to the filtering device 108 and the divider 102e for modulating the filtered signal S_{f} to generate the dividing factor N.

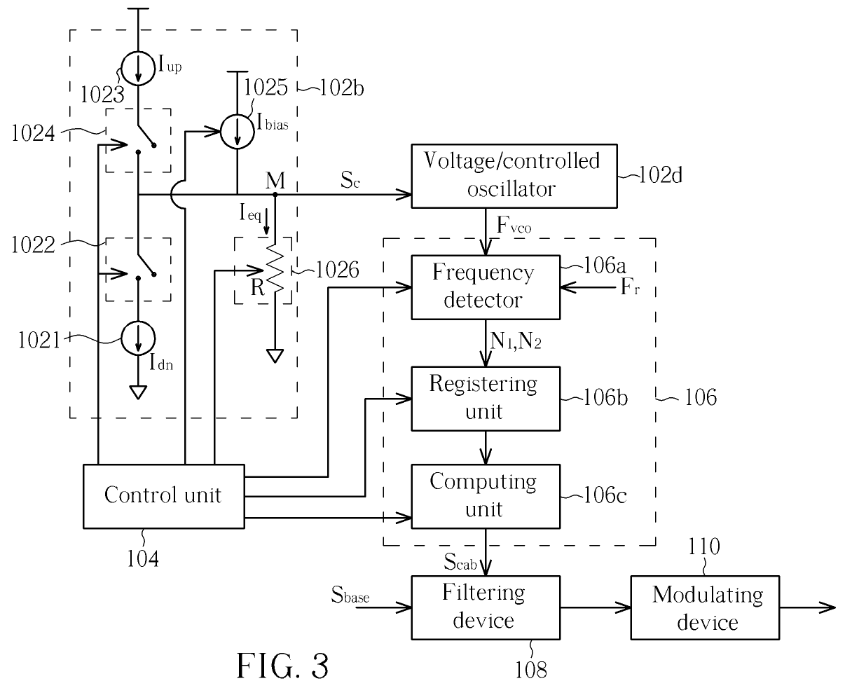

Please refer to FIG. 3. FIG. 3 is a diagram illustrating the detecting device 106 and the control signal generator 102b according to a first embodiment of the present invention. The detecting device 106 comprises a frequency detector 106a, a registering unit 106b, and a computing unit 106c. The frequency detector 106a is coupled to the voltage controlled oscillator 102d and the control unit 104 for detecting a first synthesized signal F_{vco1} and a second synthesized signal F_{vco2} to generate a first counting value N₁ and a second counting value N₂ respectively. The registering unit 106b is coupled to the frequency detector 106a and the control unit 104 for registering the first counting value N₁ and the second counting value N₂. The computing unit 106c is coupled to the registering unit 106b and the control unit 104 for generating the calibrating signal S_{cab} according to a predetermined difference value ΔN_{c} and a difference value ΔN_{c1} between the first counting value N₁ and the second counting value N₂.

Furthermore, the control signal generator 102b comprises a discharging current source 1021, a first switch 1022, a charging current source 1023, a second switch 1024, a bias current source 1025, and an impedance unit 1026. The discharging current source 1021 generates a discharging current I_{dn}. The first switch 1022 is coupled to the discharging current I_{dn} for selectively coupling the discharging current source 1021 to an output node M of the control signal generator 102b, wherein the first switch 1022 is controlled by the detected signal S_{d} in a normal mode and controlled by the control unit 104 in the calibration mode. Please note that, in order to describe the spirit of the present invention more clearly, the loop filter 102c is not shown in FIG. 3. However, those skilled in this art will readily know that the loop filter 102c can be placed between the control signal generator 102b and the voltage controlled oscillator 102d. The charging current source 1023 generates a charging current Iᵤₚ. The second switch 1024 is coupled to the charging current Iᵤₚ for selectively coupling the charging current source 1023 to the output node M of the control signal generator 102b, wherein the second switch 1024 is controlled by the detected signal S_{d} in the normal mode and controlled by the control unit 104 in the calibration mode. The bias current source 1025 is coupled to the output node M of the control signal generator 102b for generating a bias current I_{bias}. The impedance unit 1026 is coupled to the output node M of the control signal generator 102b for setting the control signal S_{c} according to an equivalent current I_{eq} flowing through the impedance unit 1026, wherein when the first switch 1022 is turned on and the second switch 1024 is turned off by the control unit 104, a first control signal S_{c1} is outputted to the voltage controlled oscillator 102d to make the voltage controlled oscillator 102d generate the first synthesized signal F_{vco1}, and when the first switch 1022 is turned off and the second switch 1024 is turned on by the control unit 104, a second control signal S_{c2} is outputted to the voltage controlled oscillator 102d to make the voltage controlled oscillator 102d generate the second synthesized signal F_{vco2}.

As known by those skilled in this art, the open-loop transfer function Tₒₚ(s) of the phase-locked loop device 102 can be shown as the following equation (1):

$$\begin{matrix}{T}_{op} ( s ) = ( \frac{{K}_{pfd} * {K}_{vco}}{N} ) * \\ ( \frac{( s * {τ}_{z 1} + 1 ) * ( s * {τ}_{z 2} + 1 ) … ( s * {τ}_{zl} + 1 )}{{s}^{m} * ( s * {τ}_{p 1} + 1 ) * ( s * {τ}_{p 2} + 1 ) … ( s * {τ}_{p l} + 1 ) *} ) \\ = {K}_{G} * L ( s ) .\end{matrix} \qquad ( 1 )$$

Wherein, K_{pfd} is the transfer function from the phase/frequency detector 102a to the control signal generator 102b, K_{vco} is the sensitivity of the voltage controlled oscillator 102d, and N is the dividing factor of the divider 102e. Therefore, the closed-loop transfer function T(s) of the phase-locked loop device 102 can then be the following equation (2):

T(s)=K_{G}*L(s)/(1+K_{G}*L(s)). (2)

After the signal generating apparatus 100 is fabricated, and as is well known by those skilled in this art, the compensation transfer function Comp(s) of the filtering device 108 can be shown as the following equation (3):

$$\begin{matrix}Comp ( s ) = 1 \text{/} {T}^{′} ( s ) \\ = ( 1 \text{/} T ( s ) ) * {G}_{cal} \\ = 1 + 1 \text{/} ( {K}_{G} * L ( s ) ) * {G}_{cal} \\ = 1 + ( N \text{/} {K}_{pfd} * {K}_{vco} ) \text{/} L ( s ) * {G}_{cal} ,\end{matrix} \qquad ( 3 )$$

wherein “′” means the real value after fabrication, and G_{cal} is the calibrating factor of the filtering device 108. Accordingly, in order to let the filtering device 108 have the transfer function that fits to the real response of the phase-locked loop device 102, the calibrating factor G_{cal} can be set as the following equation:

G_{cal}=(N′/K′_{pfd}*K′_{vco})/(N/K_{pfd}*K_{vco}). (4)

Thus, the compensation transfer function Comp(s) of the filtering device 108 becomes:

Comp(s)=(1/T′ₒₚ(s))

wherein T′ₒₚ(s) is the open-loop transfer function of the phase-locked loop device 102, K′_{pfd} is the transfer function from the phase/frequency detector 102a to the control signal generator 102b, K′_{vco} is the sensitivity of the voltage controlled oscillator 102d, and N′ is the dividing factor of the divider 102e after fabrication.

Then, the following paragraph is focused on the operation to obtain the calibrating factor G_{cal} of the signal generating apparatus 100.

Please refer to FIG. 3 again. In the ideal case, which is the case that before the signal generating apparatus 100 is fabricated, the control unit 104 controls the first switch 1022 to couple the discharging current I_{dn} to the output node M of the control signal generator 102b and opens the second switch 1024, then the first control signal S_{c1} is outputted to the voltage controlled oscillator 102d to make the voltage controlled oscillator 102d generate the first synthesized signal F_{vco1}, i.e.,

F_{vco1}=F_{free}+(I_{bias}−I_{dn})*R*K_{vco}=Fᵣ*N₁, (5)

wherein F_{free} is the frequency only generated by the bias current I_{bias}, Fᵣ is the reference frequency inputted to the frequency detector 106a, and R is the resistance of the impedance unit 1026. Accordingly, the frequency detector 106a generates the first counting value N₁ corresponding to the first synthesized signal F_{vco1}. Then, the control unit 104 controls the second switch 1024 to couple the charging current Iᵤₚ to the output node M of the control signal generator 102b and opens the first switch 1022, then the second control signal S_{c2} is outputted to the voltage controlled oscillator 102d to make the voltage controlled oscillator 102d generate the second synthesized signal F_{vco2}, i.e.,

F_{vco2}=F_{free}+(I_{bias}+Iᵤₚ)*R*K_{vco}=Fᵣ*N₂. (6)

Accordingly, the frequency detector 106a generates the second counting value N₂ corresponding to the second synthesized signal F_{vco2}. Therefore, the difference frequency between the first synthesized signal F_{vco1} and the second synthesized signal F_{vco2} is:

$$\begin{matrix}{F}_{vco 2} - {F}_{vco 1} = {F}_{r} * ( {N}_{2} - {N}_{1} ) \\ = ( {I}_{up} + {I}_{dn} ) * R * {K}_{vco} \\ = 2 * {I}_{chp} * R * {K}_{vco} \\ = A ,\end{matrix}$$

wherein, for brevity, setting Iᵤₚ=I_{dn}=I_{chp}.

Similarly, in the real case, which is the case that after the signal generating apparatus 100 is fabricated, the control unit 104 controls the first switch 1022 to couple the discharging current I_{dn}′ to the output node M of the control signal generator 102b and opens the second switch 1024, then the first control signal S_{c1}′ is outputted to the voltage controlled oscillator 102d to make the voltage controlled oscillator 102d to generate the first synthesized signal F_{vco1}′, i.e.,

F_{vco1}′=F_{free}′+(I_{bias}′−I_{dn}′)*R′*K_{vco}′=Fᵣ*N₁′, (7)

wherein “′” means the real value after fabrication. Accordingly, the frequency detector 106a generates the first counting value N₁′ corresponding to the first synthesized signal F_{vco1}′. Then, the control unit 104 controls the second switch 1024 to couple the charging current Iᵤₚ′ to the output node M of the control signal generator 102b and opens the first switch 1022, and the second control signal S_{c2}′ is outputted to the controllable oscillator 102d to make the voltage controlled oscillator 102d generate the second synthesized signal F_{vco2}′, i.e.,

F_{vco2}′=F_{free}′+(I_{bias}′+Iᵤₚ′)*R′*K_{vco}′=Fᵣ*N₂′. (8)

Accordingly, the frequency detector 106a generates the second counting value N₂′ corresponding to the second synthesized signal F_{vco2}′. Therefore, the difference frequency between the first synthesized signal F_{vco1}′ and the second synthesized signal F_{vco2}′ is:

$$\begin{matrix}{F}_{vco 2}^{′} - {F}_{vco 1}^{′} = {F}_{r} * ( {N}_{2}^{′} - {N}_{1}^{′} ) \\ = ( {I}_{up}^{′} + {I}_{dn}^{′} ) * {R}^{′} * {K}_{vco}^{′} \\ = 2 * {I}_{chp}^{′} * {R}^{′} * {K}_{vco}^{′} \\ = B ,\end{matrix}$$

similarly, for brevity, setting Iᵤₚ′=I_{dn}′=I_{chp}′.

Furthermore,

$$\begin{matrix}A / B = ( {N}_{2} - {N}_{1} ) / ( {N}_{2}^{′} - {N}_{1}^{′} ) \\ = Δ {N}_{c} / Δ {N}_{c 1} \\ = ( {I}_{chp} * R * {K}_{vco} ) / ( {I}_{chp}^{′} * {R}^{′} * {K}_{vco}^{′} ) ,\end{matrix}$$

then, according to the equation (4),

$$\begin{matrix}{G}_{cal} = ( {K}_{pfd} * {K}_{vco} * {N}^{′} ) / ( {K}_{pfd}^{′} * {K}_{vco}^{′} * N ) \\ = ( {I}_{chp} * {K}_{vco} * {N}^{′} ) / ( {I}_{chp}^{′} * {K}_{vco}^{′} * N ) ,\end{matrix}$$

$$if R = {R}^{′} , then$$

$${G}_{cal} = ( Δ {N}_{c} / Δ {N}_{c 1} ) * ( {N}^{′} / M ) .$$

Please note that, as the dividing factors N, N′ of the divider 102e are the known factors in the calibration mode and ΔN_{c} is predetermined, the computing unit 106c only computes the difference value ΔN_{c1} and sets the calibrating signal S_{cab} to be the calibrating factor G_{cal}.

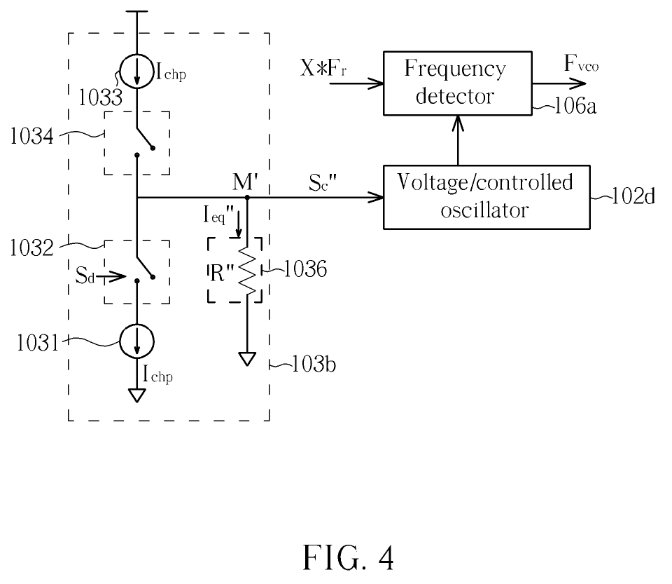

Please refer to FIG. 4. FIG. 4 is a diagram illustrating a control signal generator 103b according to a second embodiment of the present invention. The control signal generator 103b comprises a discharging current source 1031, a first switch 1032, a charging current source 1033, a second switch 1034 and an adjustable impedance unit 1036. The discharging current source 1031 generates a discharging current I_{chp}. The first switch 1032 is coupled to the discharging current I_{chp} for selectively coupling the discharging current source 1031 to an output node M′ of the control signal generator 103b, wherein the first switch 1032 is controlled by the detected signal S_{d} in a normal mode and controlled by the control unit 104 in the calibration mode. The adjustable impedance unit 1036 is coupled to the output node M′ of the control signal generator 103b for setting the control signal S_{c}″ according to an equivalent current I_{eq}″ flowing through the adjustable impedance unit 1036, wherein when either the first switch 1032 and the second switch 1034 is turned on by the control unit 104, the control unit 104 sets the adjustable impedance unit 1036 to a first impedance value R₁″ to thereby make the voltage controlled oscillator 102d generate the first synthesized signal F_{vco1}, and the control unit 104 further sets the adjustable impedance unit 1036 to a second impedance value R₂′ to thereby make the voltage controlled oscillator 102d generate the second synthesized signal F_{vco2}. Please note that, in order to describe the spirit of the present invention more clearly, the voltage controlled oscillator 102d and the frequency detector 106a are also shown in FIG. 4. Furthermore, in this embodiment, the reference frequency inputted to the frequency detector 106a is X*Fᵣ, wherein X is an integer number.

Similar to the above-mentioned embodiment control signal generator 102b, in the ideal case, before the signal generating apparatus 100 is fabricated, the control unit 104 controls the second switch 1034 to couple the charging current I_{chp} to the output node M″ of the control signal generator 103b and opens the first switch 1032, then the control unit 104 adjusts a percentage P of the adjustable impedance unit 1036 to generate the first impedance value R₁″ and the second impedance value R₂″. Accordingly, the controllable oscillator 102d generates a first difference frequency ΔF, i.e.,

$$\begin{matrix}Δ F = ( {F}_{r} * X ) * Δ {N}_{c} \\ = ( {I}_{chp} * {R}^{″} * P * {K}_{vco} ) \\ = A ,\end{matrix}$$

wherein R″*P=R₂″−R₁″.

Similarly, in the real case, which is the case that after the signal generating apparatus 100 is fabricated, the control unit 104 controls the second switch 1034 to couple the charging current I_{chp}′ to the output node M″ of the control signal generator 103b and opens the first switch 1032, then the control unit 104 adjusts a percentage P′ of the adjustable impedance unit 1036 to generate the first impedance value R₁′″ and the second impedance value R₂′″. Accordingly, the voltage controlled oscillator 102d generates a first difference frequency ΔF′, i.e.,

$$\begin{matrix}Δ {F}^{′} = ( {F}_{r} * X ) * Δ {N}_{c}^{′} \\ = ( {I}_{chp}^{′} * {R}^{′′′} * {P}^{′} * {K}_{vco}^{′} ) \\ = B ,\end{matrix}$$

wherein R′″*P′=R₂′″−R₁′″, and “″” means the real value after fabrication.

Furthermore,

$$\begin{matrix}A \text{/} B = ( {I}_{chp} * {R}^{″} * P * {K}_{vco} ) / ( {I}_{chp}^{′} * {R}^{′′′} * {P}^{′} * {K}_{vco}^{′} ) \\ = ( {I}_{chp} * {K}_{vco} ) / ( {I}_{chp}^{′} * {K}_{vco}^{′} ) . \\ if {R}^{″} * P is calibrated to equal {R}^{′′′} * {P}^{′} , \\ = Δ {N}_{c} / Δ {N}_{c}^{′} .\end{matrix}$$

Accordingly, the calibrating factor G_{cal} can be obtained, i.e.,

G_{cal}=(ΔN_{c}/ΔN_{c}′)*(N′/N).

Please note that, in other embodiments of the present invention, the control signal generator 102b can be implemented by replacing the bias current source 1025 with an adjustable bias current source, which is controlled by the control unit 104. Those skilled in this art can easily understand the operation of this embodiment after reading the disclosure of the present invention, thus the detailed description is omitted here for brevity.

Furthermore, in another embodiment of the present invention, the control signal generator 102b can be implemented by replacing the impedance unit 1026 with an adjustable impedance unit, which is controlled by the control unit 104. Those skilled in this art can easily understand the operation of this embodiment after reading the disclosure of the present invention, thus the detailed description is omitted here for brevity.

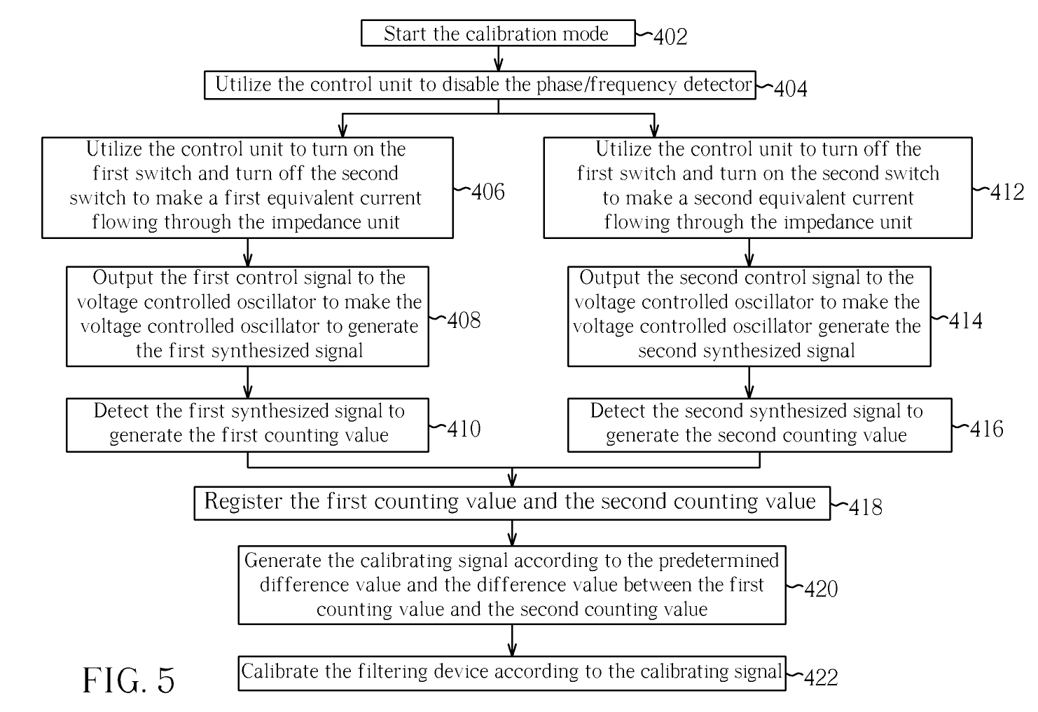

Please refer to FIG. 5. FIG. 5 is a flowchart illustrating a signal generating method employed by the signal generating apparatus 100 as shown in FIG. 2. In other words, the signal generating method is described through the fractional N PLL (Phase-locked loop) synthesizer with the adaptive compensation filter, i.e., the filtering device 108. The signal generating method comprises the following steps:

Step 402: Start the calibration mode;

Step 404: Utilize the control unit 104 to disable the phase/frequency detector 102a;

Step 406: Utilize the control unit 104 to turn on the first switch 1022 and turn off the second switch 1024 to make a first equivalent current I_{eq1} flow through the impedance unit 1026;

Step 408: Output the first control signal S_{c1} to the voltage controlled oscillator 102d to make the voltage controlled oscillator 102d to generate the first synthesized signal F_{vco1};

Step 410: Detect the first synthesized signal F_{vco1} to generate the first counting value N₁, go to step 418;

Step 412: Utilize the control unit 104 to turn off the first switch 1022 and turn on the second switch 1024 to make a second equivalent current I_{eq2} flow through the impedance unit 1026;

Step 414: Output the second control signal S_{c2} to the voltage controlled oscillator 102d to make the voltage controlled oscillator 102d generate the second synthesized signal F_{vco2};

Step 416: Detect the second synthesized signal F_{vco2} to generate the second counting value N₂;

Step 418: Register the first counting value N₁ and the second counting value N₂;

Step 420: Generate the calibrating signal S_{cab} according to the predetermined difference value ΔN_{c} and the difference value ΔN_{c1} between the first counting value N₁ and the second counting value N₂;

Step 422: Calibrate the filtering device 108 according to the calibrating signal S_{cab}.

In step 404, when the control unit 104 disables the phase/frequency detector 102a, the control signal generator 102b is not affected by the detected signal S_{d} of the phase/frequency detector 102a. In other words, the signal generating apparatus 100 is an open loop under the calibration mode.

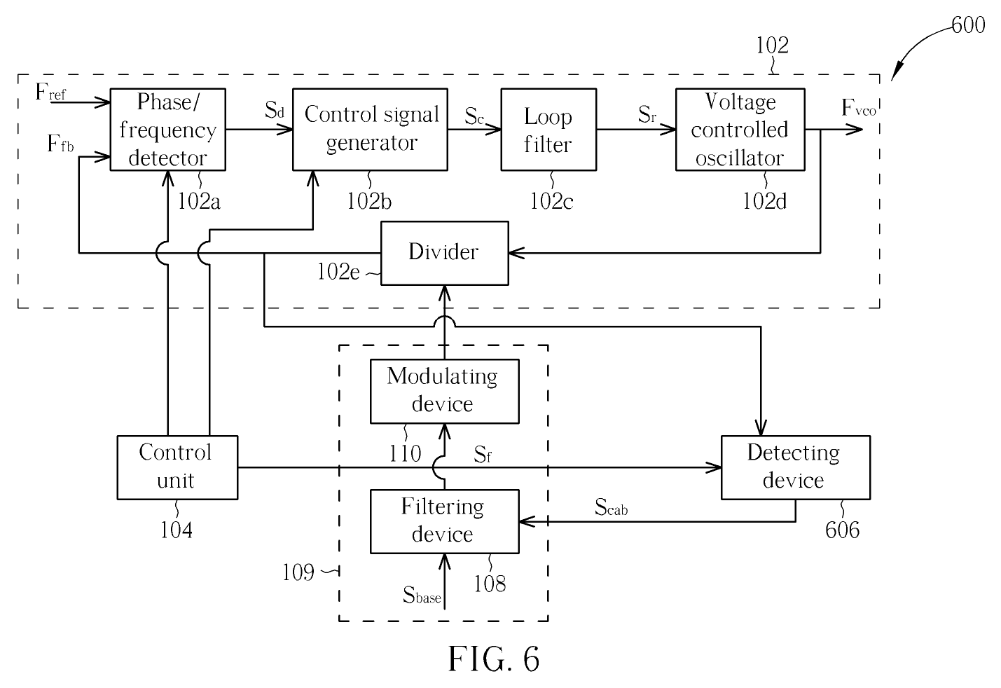

Please refer to FIG. 6. FIG. 6 is a diagram illustrating a second exemplary embodiment of a signal generating apparatus 600 according to the present invention. The signal generating apparatus 600 generates a synthesized signal F_{vco} according to an input signal S_{base}, and the signal generating apparatus 600 comprises a phase-locked loop device 102, a control unit 104, a detecting device 606, and a correction device 109 having a filtering device 108 and a modulating device 110 included therein. The circuit configuration of the signal generating apparatus 600 shown in FIG. 6 is similar to that of the signal generating apparatus 100 shown in FIG. 2. The major different between these two exemplary embodiments is that the detecting device 606 is coupled to the divider 102e for detecting the feedback signal F_{fb} to generate the calibrating signal S_{cab} in the calibration mode. In addition, the operation of the detecting device 606 shown in FIG. 6 is similar to that of the detecting device 106 shown in FIG. 2, FIG. 3, and FIG. 4. The detecting device 606 can be easily realized by applying slight modifications to the detecting device 106 shown in FIG. 3. For example, the detecting device 606 can be implemented by coupling the frequency detector 106a shown in FIG. 3 to the divider 102e for detecting a first feedback signal and a second feedback signal to generate the first counting value N₁ and the second counting value N₂ respectively. After the registering unit 106b registers the first counting value N₁ and the second counting value N₂, the computing unit 106c generates the calibrating signal S_{cab} according to a predetermined difference value and a difference value between the first counting value N₁ and the second counting value N₂. In this way, the same objective of generating the desired calibrating signal S_{cab} is achieved. As components with the same reference numeral in FIG. 2 and FIG. 6 have the same operation and functionality, further description is omitted here for brevity.

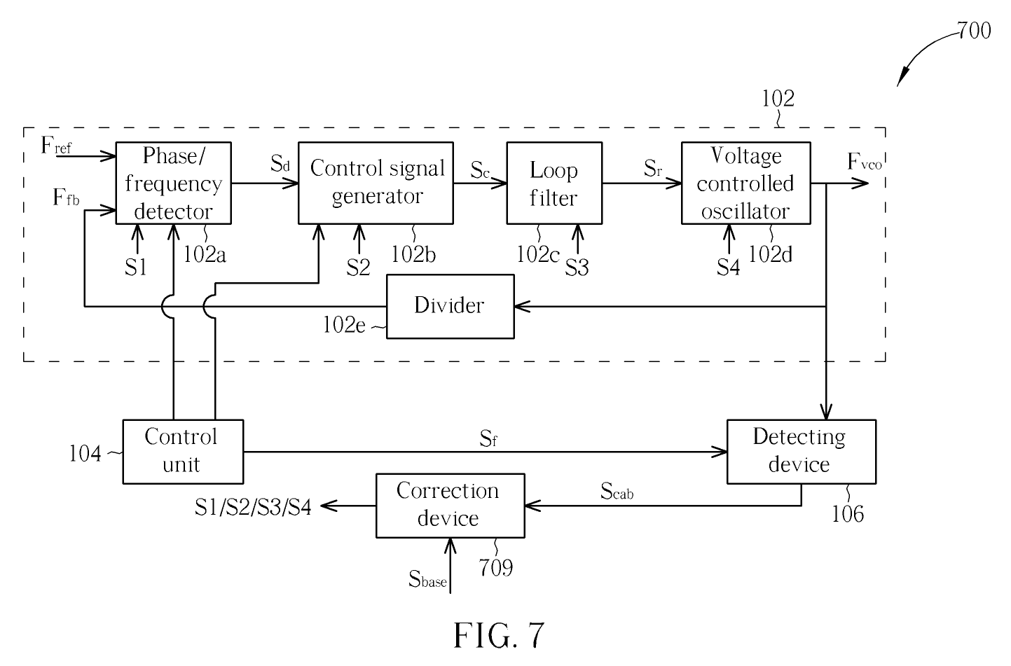

In above embodiments, the phase locked loop circuit generates a synthesized signal for a designated frequency band by adjusting the dividing number of the divider. However, other alternative designs without departing from the spirit of the present invention are possible. These alternative designs all fall within the scope of the present invention. Please refer to FIG. 7. FIG. 7 is a diagram illustrating a third exemplary embodiment of a signal generating apparatus 700 according to the present invention. The signal generating apparatus 700 generates a synthesized signal F_{vco} according to an input signal S_{base}, and the signal generating apparatus 700 comprises a phase-locked loop device 102, a control unit 104, a detecting device 106, and a correction device 709. The circuit configuration of the signal generating apparatus 700 shown in FIG. 7 is similar to that of the signal generating apparatus 100 shown in FIG. 2. The major different between these two exemplary embodiments is that the correction device 709 generates an output S1, S2, S3, or S4 according to the calibrating signal S_{cab} derived by the detecting device 106 in the calibration mode. For example, in order to achieve the same objective of generating a synthesized signal for a designated frequency band, the correction device 709 could generate the output S1 to the phase/frequency detector 102a to adjust the phase/frequency detector 102a, generate the output S2 to the control signal generator 102b (e.g., a charge pump) to adjust the control signal generator 102b, generate the output S3 to the loop filter 102c to adjust the loop filter 102c, or generate the output S4 to the voltage controlled oscillator 102d to adjust the voltage controlled oscillator 102d. As components with the same reference numeral in FIG. 2 and FIG. 7 have the same operation and functionality, further description is omitted here for brevity.

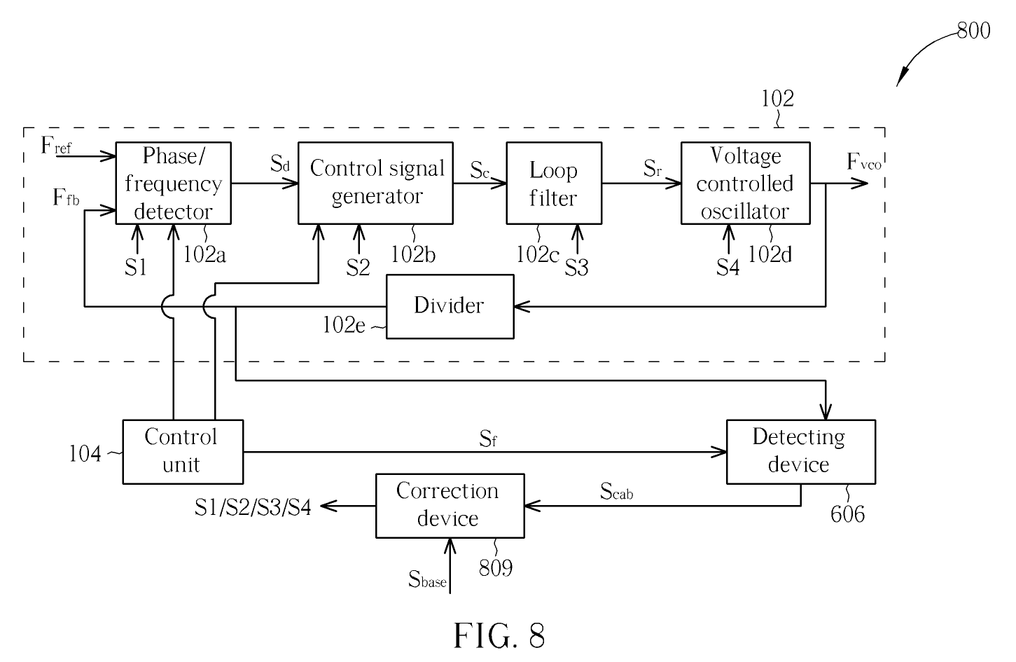

Please refer to FIG. 8. FIG. 8 is a diagram illustrating a fourth exemplary embodiment of a signal generating apparatus 800 according to the present invention. The signal generating apparatus 800 generates a synthesized signal F_{vco} according to an input signal S_{base}, and the signal generating apparatus 800 comprises a phase-locked loop device 102, a control unit 104, a detecting device 606, and a correction device 809. The correction device 809 is implemented to generate an output S1, S2, S3, or S4 according to the calibrating signal S_{cab} derived by the detecting device 606 in the calibration mode. The circuit configuration of the signal generating apparatus 800 shown in FIG. 8 is similar to that of the signal generating apparatus 700 shown in FIG. 7. The major different between these two exemplary embodiments is that the detecting device 606 is coupled to the divider 102e for detecting the feedback signal F_{fb} to generate the calibrating signal S_{cab} in the calibration mode. As a person skilled in the art can readily understand operation of the signal generating apparatus 800 after reading above paragraphs, further description is omitted here for brevity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A signal generating apparatus, for generating a synthesized signal according to an input signal, comprising:
a phase-locked loop device, comprising:
a phase/frequency detector, for generating a detected signal according to a reference oscillating signal and a feedback signal;
a control signal generator, coupled to the phase/frequency detector, for generating a control signal according to the detected signal;
a voltage controlled oscillator, coupled to the control signal generator, for generating the synthesized signal according to the control signal; and
a divider, coupled to the voltage controlled oscillator, for dividing the synthesized signal according to a dividing factor for generating the feedback signal; and
a control unit, coupled to the control signal generator, for controlling the control signal generator to adjust the control signal in a calibration mode to thereby adjust a frequency of the synthesized signal, wherein the phase/frequency detector does not output the detected signal to the control signal generator in the calibration mode.

2. The signal generating apparatus of claim 1, further comprising:
a detecting device, coupled to the voltage controlled oscillator, for detecting the synthesized signal to generate a calibrating signal in the calibration mode.

3. The signal generating apparatus of claim 2, further comprising:
a correction device, coupled to the detecting device and the phase-locked loop device, for generating an output to the phase/frequency detector according to the calibrating signal.

4. The signal generating apparatus of claim 2, further comprising:
a correction device, coupled to the detecting device and the phase-locked loop device, for generating an output to the voltage controlled oscillator according to the calibrating signal.

5. The signal generating apparatus of claim 2, further comprising:
a correction device, coupled to the detecting device and the phase-locked loop device, for generating an output to the control signal generator according to the calibrating signal.

6. The signal generating apparatus of claim 2, further comprising:
a correction device, coupled to the detecting device and the phase-locked loop device, for generating an output to the loop filter according to the calibrating signal.

7. The signal generating apparatus of claim 2, wherein the detecting device comprises:
a frequency detector, coupled to the voltage controlled oscillator, for detecting a first synthesized signal and a second synthesized signal to generate a first counting value and a second counting value respectively;
a registering unit, coupled to the frequency detector, for registering the first counting value and the second counting value; and
a computing unit, coupled to the registering unit, for generating the calibrating signal according to a predetermined difference value and a difference value between the first counting value and the second counting value.

8. The signal generating apparatus of claim 7, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and controlled by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and controlled by the control unit in the calibration mode;
a bias current source, coupled to the output node of the control signal generator, for generating a bias current; and
an impedance unit, coupled to the output node of the control signal generator, for setting the control signal according to an equivalent current flowing through the impedance unit, wherein when the first switch is turned on and the second switch is turned off by the control unit, a first control signal is outputted to the controllable oscillator to make the controllable oscillator generate the first synthesized signal, and when the first switch is turned off and the second switch is turned on by the control unit, a second control signal is outputted to the controllable oscillator to make the controllable oscillator generate the second synthesized signal.

9. The signal generating apparatus of claim 7, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and controlled by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and controlled by the control unit in the calibration mode;
an adjustable impedance unit, coupled to the output node of the control signal generator and the control unit, for setting the control signal according to the current flowing through the impedance unit, wherein when one of the first switch and the second switch is turned on by the control unit, the control unit sets the adjustable impedance unit to a first impedance value to thereby make the controllable oscillator generate the first synthesized signal, and the control unit further sets the adjustable impedance unit to a second impedance value to thereby make the voltage controlled oscillator generate the second synthesized signal.

10. The signal generating apparatus of claim 7, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and turned off by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and turned off by the control unit in the calibration mode;
an adjustable bias current source, coupled to the output node of the control signal generator and the control unit, for generating a bias current; and
an impedance unit, coupled to the output node of the control signal generator, for setting the control signal according to an equivalent current flowing through the impedance unit, wherein in the calibration mode, the control unit sets the adjustable bias current source to provide a first bias current to thereby make the voltage controlled oscillator generate the first synthesized signal, and the control unit further sets the adjustable bias current source to provide a second bias current to thereby make the voltage controlled oscillator generate the second synthesized signal.

11. The signal generating apparatus of claim 7, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and turned off by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and turned off by the control unit in the calibration mode;
a bias current source, coupled to the output node of the control signal generator, for generating a bias current; and
an adjustable impedance unit, coupled to the output node of the control signal generator and the control unit, for setting the control signal according to an equivalent current flowing through the impedance unit, wherein in the calibration mode, the control unit sets the adjustable impedance unit to a first impedance value to thereby make the voltage controlled oscillator generate the first synthesized signal, and the control unit further sets the adjustable impedance unit to a second impedance value to thereby make the controllable oscillator generate the second synthesized signal.

12. The signal generating apparatus of claim 1, further comprising:
a detecting device, coupled to the divider, for detecting the synthesized signal to generate a calibrating signal in the calibration mode.

13. The signal generating apparatus of claim 12, further comprising:
a correction device, coupled to the detecting device and the phase-locked loop device, for generating an output to the phase/frequency detector according to the calibrating signal.

14. The signal generating apparatus of claim 12, further comprising:
a correction device, coupled to the detecting device and the phase-locked loop device, for generating an output to the voltage controlled oscillator according to the calibrating signal.

15. The signal generating apparatus of claim 12, further comprising:
a correction device, coupled to the detecting device and the phase-locked loop device, for generating an output to the control signal generator according to the calibrating signal.

16. The signal generating apparatus of claim 12, further comprising:
a correction device, coupled to the detecting device and the phase-locked loop device, for generating an output to the loop filter according to the calibrating signal.

17. The signal generating apparatus of claim 12, further comprising:
a filtering device, coupled to the detecting device, for filtering the input signal and calibrating the input signal according to the calibrating signal to generate a filtered signal; and
a modulating device, coupled to the filtering device and the divider, for modulating the filtered signal to generate the dividing factor.

18. The signal generating apparatus of claim 12, wherein the detecting device comprises:
a frequency detector, coupled to the divider, for detecting a first feedback signal and a second feedback signal to generate a first counting value and a second counting value respectively;
a registering unit, coupled to the frequency detector, for registering the first counting value and the second counting value; and
a computing unit, coupled to the registering unit, for generating the calibrating signal according to a predetermined difference value and a difference value between the first counting value and the second counting value.

19. The signal generating apparatus of claim 1 8, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and controlled by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and controlled by the control unit in the calibration mode;
a bias current source, coupled to the output node of the control signal generator, for generating a bias current; and
an impedance unit, coupled to the output node of the control signal generator, for setting the control signal according to an equivalent current flowing through the impedance unit, wherein when the first switch is turned on and the second switch is turned off by the control unit, a first control signal is outputted to the controllable oscillator to make the controllable oscillator generate the first synthesized signal, and when the first switch is turned off and the second switch is turned on by the control unit, a second control signal is outputted to the controllable oscillator to make the controllable oscillator generate the second synthesized signal.

20. The signal generating apparatus of claim 18, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and controlled by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and controlled by the control unit in the calibration mode;
an adjustable impedance unit, coupled to the output node of the control signal generator and the control unit, for setting the control signal according to the current flowing through the impedance unit, wherein when one of the first switch and the second switch is turned on by the control unit, the control unit sets the adjustable impedance unit to a first impedance value to thereby make the controllable oscillator generate the first synthesized signal, and the control unit further sets the adjustable impedance unit to a second impedance value to thereby make the voltage controlled oscillator generate the second synthesized signal.

21. The signal generating apparatus of claim 18, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and turned off by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and turned off by the control unit in the calibration mode;
an adjustable bias current source, coupled to the output node of the control signal generator and the control unit, for generating a bias current; and
an impedance unit, coupled to the output node of the control signal generator, for setting the control signal according to an equivalent current flowing through the impedance unit, wherein in the calibration mode, the control unit sets the adjustable bias current source to provide a first bias current to thereby make the voltage controlled oscillator generate the first synthesized signal, and the control unit further sets the adjustable bias current source to provide a second bias current to thereby make the voltage controlled oscillator generate the second synthesized signal.

22. The signal generating apparatus of claim 1 8, wherein the control signal generator comprises:
a charging current source, for generating a charging current;
a first switch, coupled to the charging current, for selectively coupling the charging current source to an output node of the control signal generator, wherein the first switch is controlled by the detected signal in a normal mode and turned off by the control unit in the calibration mode;
a discharging current source, for generating a discharging current;
a second switch, coupled to the discharging current, for selectively coupling the discharging current source to the output node of the control signal generator, wherein the second switch is controlled by the detected signal in the normal mode and turned off by the control unit in the calibration mode;
a bias current source, coupled to the output node of the control signal generator, for generating a bias current; and
an adjustable impedance unit, coupled to the output node of the control signal generator and the control unit, for setting the control signal according to an equivalent current flowing through the impedance unit, wherein in the calibration mode, the control unit sets the adjustable impedance unit to a first impedance value to thereby make the voltage controlled oscillator generate the first synthesized signal, and the control unit further sets the adjustable impedance unit to a second impedance value to thereby make the controllable oscillator generate the second synthesized signal.
